(19) United States
(12) Patent Application Publication
(10) Pub. No.: US 2014/0218879 A1
(43) Pub. Date: Aug. 7, 2014

(54) ELECTRONIC DEVICE WITH MOTHERBOARD

(71) Applicants: HONG FU JIN PRECISION INDUSTRY (SHENZHEN) CO.,LTD., Shenzhen (CN); HON HAI PRECISION INDUSTRY CO., LTD., New Taipei (TW)

(72) Inventors: XIAO-GANG YIN, Shenzhen (CN); LI-REN FU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/830,578

(22) Filed: Mar. 14, 2013

(30) Foreign Application Priority Data
Feb. 5, 2013 (CN) 201310044615.X

(51) Int. Cl. H05K 7/14

(52) U.S. Cl. CPC H05K 7/1417
USPC 361/759

(57) ABSTRACT

An electronic device includes a motherboard defining a number of through holes, a bottom wall forming a number of posts, and a fixing member including a fixing body mounted to the bottom wall and a movable body pivotably mounted to the fixing body. Each through hole includes a first hole and a second hole communicating with each other. Each post includes a supporting portion, a head, and a neck. The fixing body defines a slot. The movable body includes a main portion, a hook, and a projection extending from an end of the main portion. The heads are extended through the first holes. The necks abut against end walls bounding the corresponding second holes. The motherboard is sandwiched between the heads and the supporting portions. The hook is engaged in the slot, and the projection abuts against an end of the motherboard adjacent to the fixing member.

### BACKGROUND

1. Technical Field

The present disclosure relates to an electronic device including a motherboard.

2. Description of Related Art

Motherboards are often mounted to bottom walls of chassis by screws, which is time consuming in installing and uninstalling.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electronic device.

FIG. 2 is an enlarged view of the circled portion II of FIG. 1.

FIG. 3 is an enlarged view of the circled portion III of FIG. 1.

FIG. 4 is an assembled, isometric view of FIG. 1.

FIG. 5 is similar to FIG. 4, but showing a state of use.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

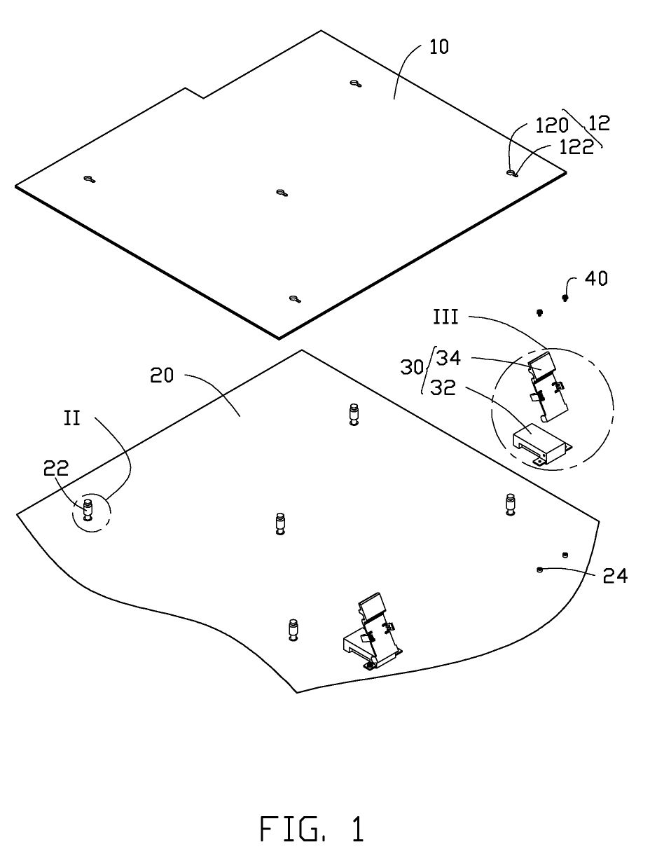

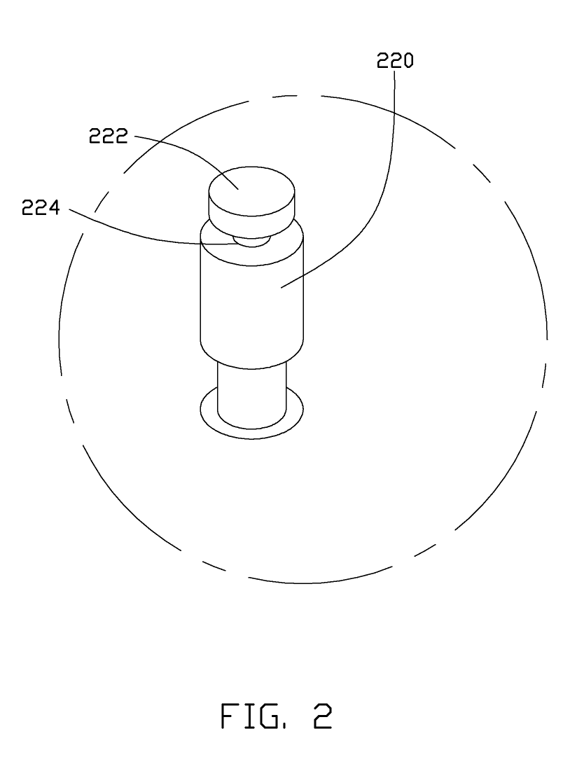

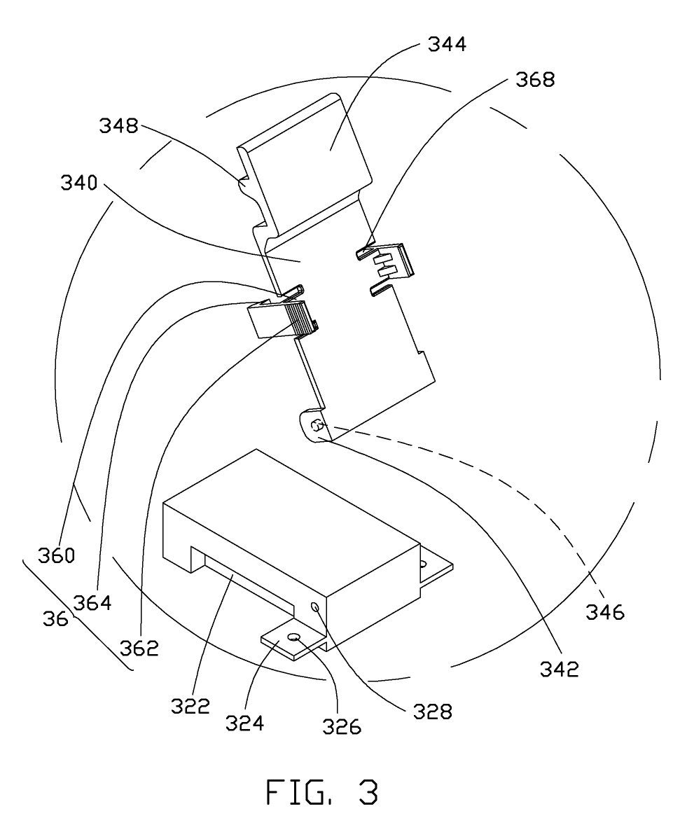

FIGS. 1 to 3 show an exemplary embodiment of an electronic device. The electronic device includes a bottom wall 20, a motherboard 10, and two fixing members 30.

The motherboard 10 defines a plurality of through holes 12. Each through hole 12 includes a first hole 120 and a second hole 122 communicating with the first hole 120. The first hole 120 is greater than the second hole 122 in width.

A plurality of posts 22 extends from the bottom wall 20, corresponding to the through holes 12. Two standoffs 24 protrude from the bottom wall 20, adjacent to the posts 22. Each post 22 includes a supporting portion 220 connected to the bottom wall 20, a head 222, and a neck 224 connected between the supporting portion 220 and the head 222. A diameter of the head 222 is greater than a diameter of the neck 224 and a diameter of the second holes 122, but less than a diameter of the supporting portion 220 and a diameter of the first holes 120.

Each fixing member 30 includes a fixing body 32 and a movable body 34.

The fixing body 32 defines two slots 322 in lower portions of opposite sides.

Two tabs 324 extend from first ends of the opposite sides of the fixing body 32, each tab 324 defining a fixing hole 326. Two pivot holes 328 are defined in the first ends of the opposite sides of the fixing member 32, above the corresponding tabs 324.

The movable body 34 includes a main portion 340, two extension pieces 342 perpendicularly extending from first ends of opposite sides of the main portion 340; a blocking portion 344 connected to a second end of the main portion 340 opposite to the first end; and two latching portions 36 connected to centers of the opposite sides of the main portion 340. Each latching member 36 includes a connecting piece 360 coplanar with the main portion 340 and connected to the corresponding side of the main portion 340. An operation piece 362 perpendicularly extending from a distal end of the connecting piece 360 away from the main portion 340 in a direction opposite to the extension pieces 342, and a hook 364 perpendicularly extending from the distal end of the connecting piece 360 away from the operation piece 362. An antiskid portion is formed at an outer surface of each operation piece 362. Two narrow slots 368 are defined in the main portion 340, at opposite sides of each connecting piece 360; therefore, the connecting pieces 360 are deformable. A pin 342 protrudes from an inner surface of each extension piece 342 toward the other extension piece 342. A projection 348 protrudes from a bottom surface of the blocking portion 344.

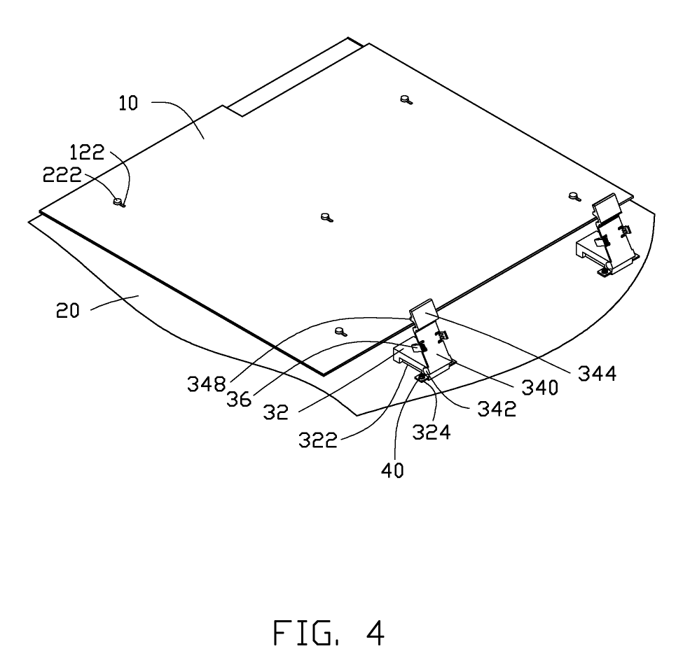

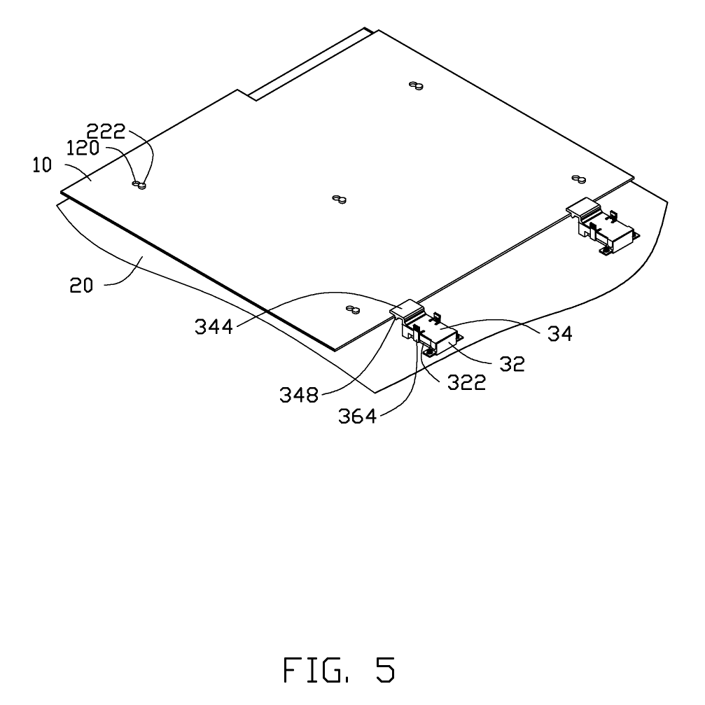

FIGS. 4 and 5 show that in assembly, two fasteners 40, such as screws, extend through the fixing holes 326 of each fixing body 32 and then are engaged in two standoffs 24, thereby fixing the fixing body 32 to the bottom wall 20. A second end of the fixing body 32 opposite to the fixing holes 326 facing toward the posts 22. The pins 346 of the corresponding movable member 34 are pivotably inserted into the pivot holes 328 of the fixing body 32, thereby pivotably mounting the movable body 34 to the fixing body 32.

The motherboard 10 is attached to the bottom wall 20, with the second holes 122 facing the fixing members 30. The heads 222 extend through the first holes 120, to allow the motherboard 10 to be supported on tops of the supporting portions 220. The motherboard 10 is then slid away from the fixing member 30, until the necks 224 are abutted against end walls bounding the corresponding second holes 122 and away from the corresponding first holes 120. The motherboard 10 is sandwiched between the supporting portions 220 and the heads 222.

The movable bodies 34 are then pivoted toward the motherboard 10, until the hooks 364 are engaged in the corresponding cutouts 322. The projections 348 abut against an end of the motherboard 10 adjacent to the fixing members 30, and the blocking portions 344 abut a top of the motherboard 10, thereby fixing the motherboard 10 to the bottom wall 20.

In another embodiment, the blocking portion 344 can be omitted. The projection 348 protrudes from a bottom surface of the main portion 340.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An electronic device, comprising:
a bottom wall forming a plurality of posts; each post comprising a supporting portion connected to the bottom wall, a head, and a neck connected between the supporting portion and the head, wherein a diameter of the neck is less than diameters of the head and the supporting portion;
a motherboard defining a plurality of through holes; each through hole comprising a first hole and a second hole communicated with the first hole, wherein the first hole is greater than the second hole in width, the diameter of the neck is less than the width of the second hole, the diameter of the head is less than the width of the first hole and greater than the width of the second hole;
a fixing member comprising a fixing body mounted to the bottom wall and defines a slot, and a movable body, the movable body comprising a main portion with a first end pivotably mounted to the fixing body, a hook connected to the main portion, and a projection extending from a second end of the main portion opposite to the first end;
wherein the heads are operable of extending through the first holes, the necks abut against end walls bounding the corresponding second holes and away from the corresponding first holes, the motherboard is sandwiched between the heads and the supporting portions, the hook is engaged in the slot, the projection abuts against an end of the motherboard adjacent to the fixing member.

2. The electronic device of claim 1, wherein an operation piece extends up from a top end of the hook.

3. The electronic device of claim 1, wherein the hook is connected to the main portion through a connecting piece, two slots are defined in the main portion at opposite sides of the connecting piece.

4. The electronic device of claim 1, wherein a blocking portion extends out from the second end of the main portion to abut against a top of the motherboard.

5. The electronic device of claim 1, wherein the fixing body defines two pivot holes, two extension pieces extend down from opposite sides of the main portion of the movable member, a pin extends from an inner surface of each extension piece to pivotably engage in one of the pivot holes.

6. The electronic device of claim 1, wherein two standoffs protrude from the bottom wall, two tabs extend from opposite sides of the fixing body, two screws extend through the tabs to be engaged in the standoffs.
